(19) United States
(12) Patent Application Publication
(10) Pub. No.: US 2024/0061037 A1
(43) Pub. Date: Feb. 22, 2024

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Hao-Cheng Hou, Hsinchu City (TW); Jung-Wei Cheng, Hsinchu City (TW); Tsung-Ding Wang, Tainan (TW); Chien-Hsun Lee, Hsin-chu County (TW)

(73) Assignee: Taiwan Semiconductor Manufacturing Company, Ltd., Hsinchu (TW)

(21) Appl. No.: 17/890,199

(22) Filed: Aug. 17, 2022

(51) Int. Cl. G01R 31/28; G01R 1/073; H01L 21/48; H01L 23/498

(52) U.S. Cl. CPC G01R 31/2896; G01R 1/07378; G01R 1/07342; G01R 31/2889; H01L 21/4853; H01L 21/4857; H01L 21/486; H01L 23/49816; H01L 23/49822; H01L 23/49833; H01L 23/49838

(57) ABSTRACT

A package structure includes a substrate component, a redistribution structure, a package structure, and a probe head. The substrate component is laterally covered by an insulating encapsulation. The redistribution structure is disposed over the substrate component and the insulating encapsulation and electrically connected with the substrate component at a first side, wherein the redistribution structure comprises: a dielectric layer at a second side opposite to the first side; at least one conductive pad disposed in the dielectric layer, wherein a portion of the at least one conductive pad is exposed by the dielectric layer; and at least one conductive pattern in contact with the portion of the at least one conductive pad, wherein a hardness of the at least one conductive pattern is greater than a hardness of the at least one conductive pad. The probe head is electrically connected with the at least one conductive pattern and the at least one conductive pad.

### BACKGROUND

In semiconductor integrated circuit manufacturing, integrated circuits (ICs) are conventionally tested during manufacturing and prior to shipment to ensure proper operation. Wafer testing is a testing technique commonly used in production testing of wafer-mounted semiconductor ICs where a temporary electrical connection is established between automatic test equipment (ATE) and ICs formed on the wafer to demonstrate proper performance of the ICs. Components used in wafer testing include an ATE test board, a multilayer printed circuit board connected to the ATE test board which transfers test signals between the ATE test board and a probe card assembly. Conventional probe card assemblies include a probe head having a plurality of flexible probing tips attached thereto and a substrate having contact pads which the flexible probing tips touch with. In conventional probe card assemblies, the hardness of the contact pads in the substrate is relatively low, such that the contact pads can not sustain from repeatedly touch-down by the flexible probing tips.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1H are schematic cross-sectional views illustrating a manufacturing process of a package structure in accordance with some embodiments of the disclosure.

FIG. 2 is a schematic cross-sectional view illustrating a package structure in accordance with some alternative embodiments of the disclosure.

FIG. 3 is a schematic cross-sectional view illustrating a package structure in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

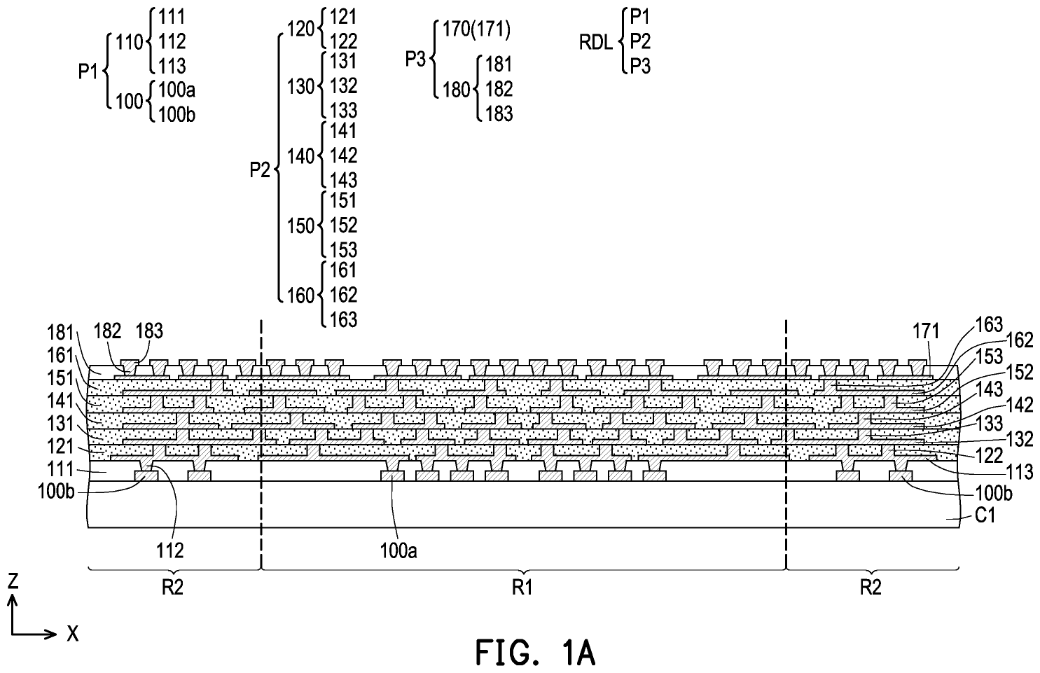

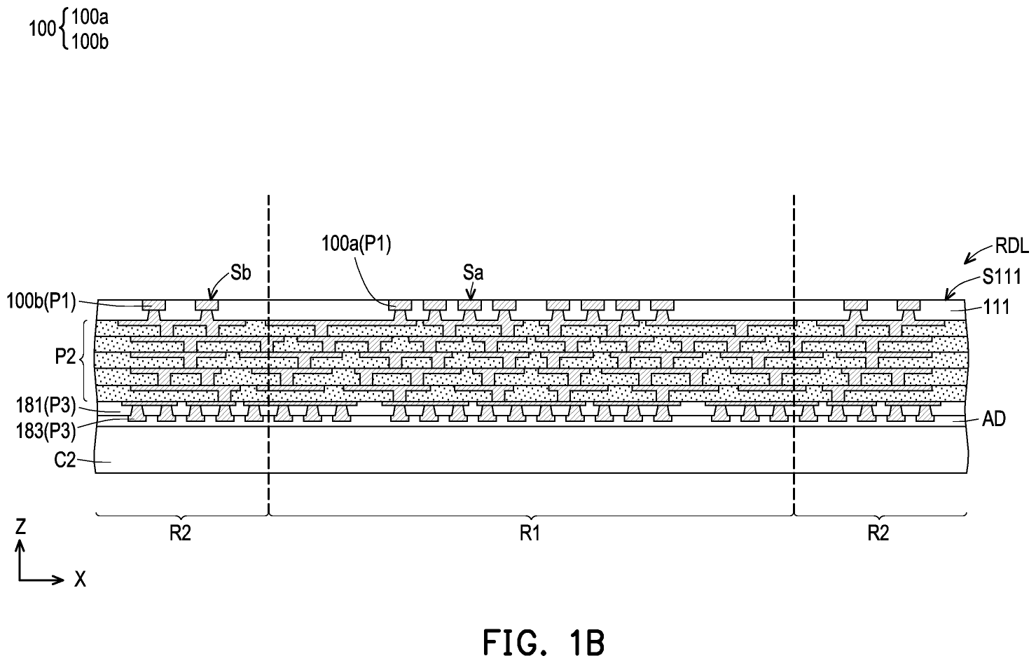

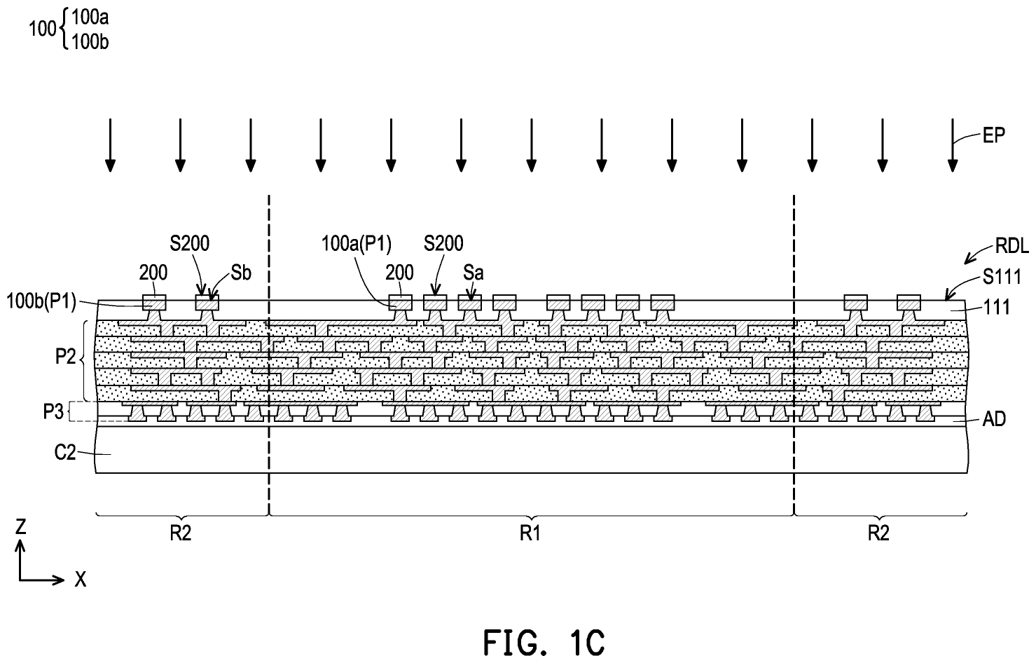

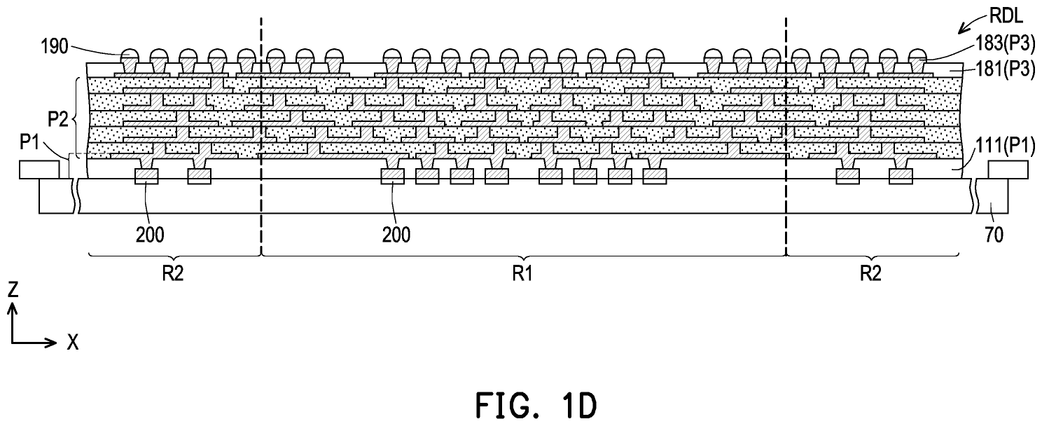

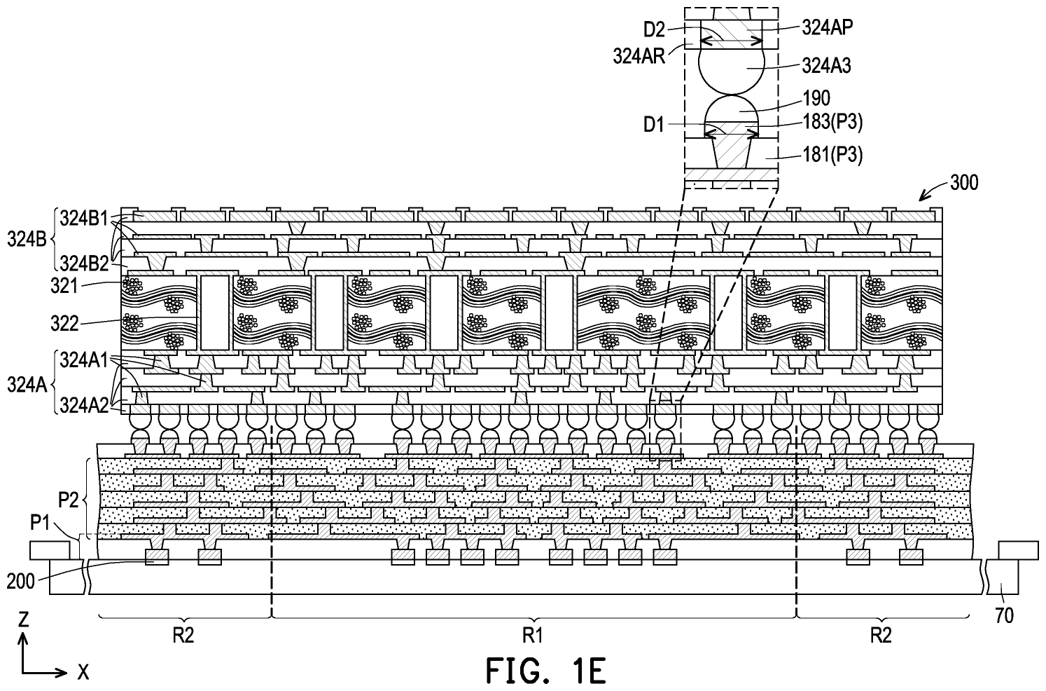

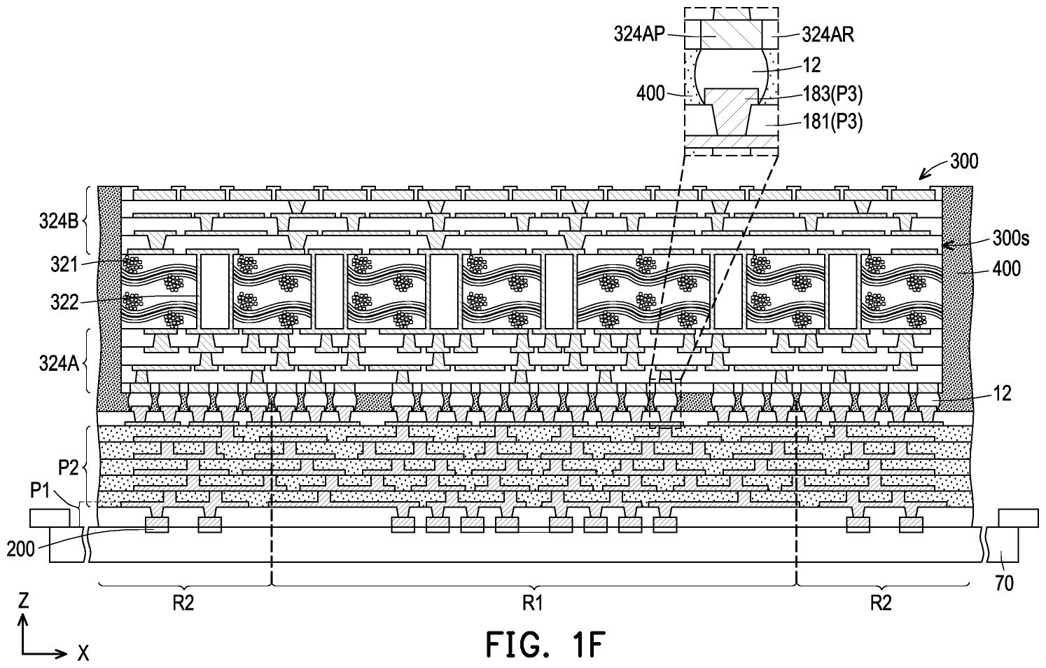

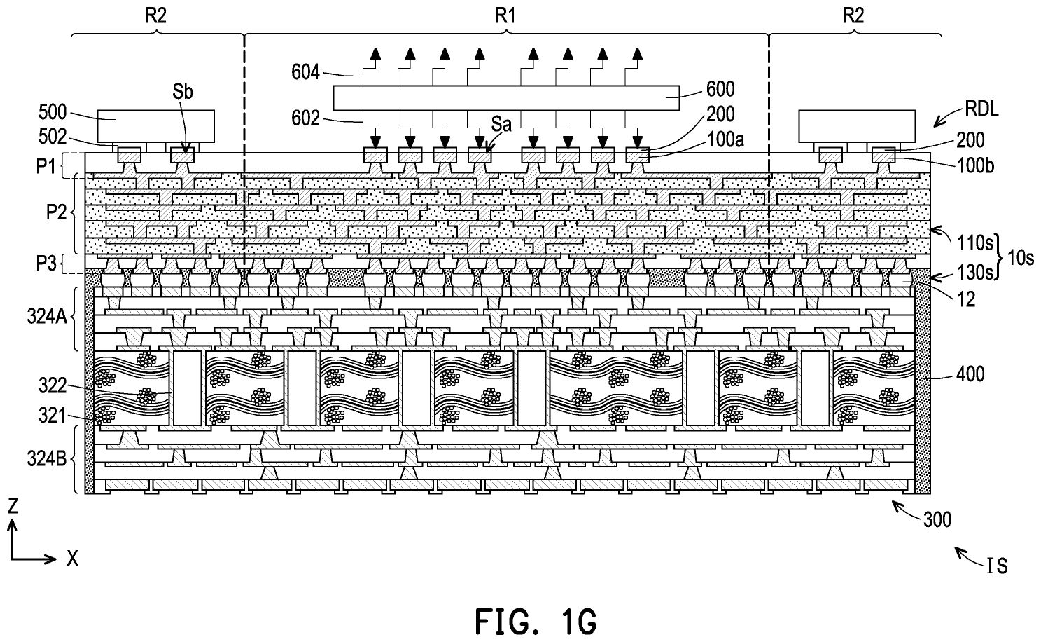

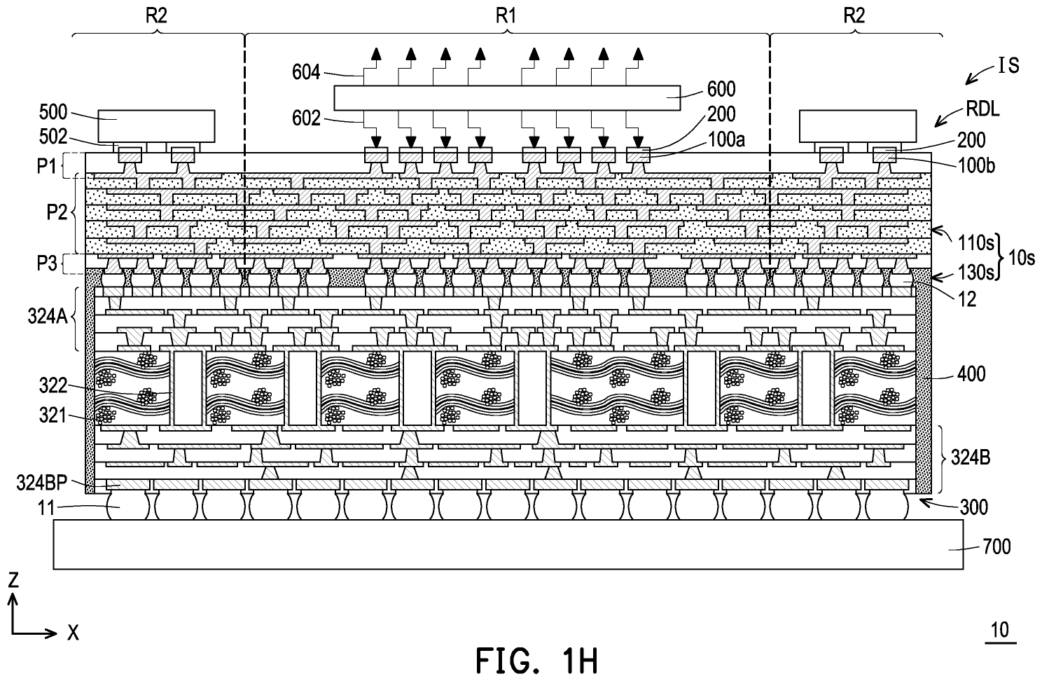

FIG. 1A to FIG. 1H are schematic cross-sectional views illustrating a manufacturing process of a package structure 10 in accordance with some embodiments of the disclosure. Referring to FIG. 1A, a redistribution structure RDL is formed over a carrier C1. In some embodiments, the carrier C1 is a glass substrate, a metal plate, a plastic supporting board or the like, but other suitable substrate materials may be used as long as the materials are able to withstand the subsequent steps of the process. In some embodiments, the carrier C1 is provided in a wafer form. That is, the carrier C1 has a circular shape. Alternatively, the carrier C1 may have a rectangular shape or other suitable shape. The carrier C1 is planar to accommodate the formation of features subsequently formed thereon.

In some embodiments, the redistribution structure RDL includes a first portion P1, a second portion P2 over the first portion P1, and a third portion P3 over the second portion P2. In some embodiments, the formation of the redistribution structure RDL includes: first forming the first portion P1 on the carrier C1; and then forming the second portion P2 on the first portion P1 over the carrier C1; and finally forming the third portion P3 on the second portion P2 o over the carrier C1.

As shown in FIG. 1A, the first portion P1 includes a first layer 100 and a second layer 110 overlying the first layer 100, the first layer 100 includes a plurality of conductive pads 100a and a plurality of conductive pads 100b, and the second layer 110 includes a dielectric layer 111, a plurality of conductive vias 112 and a plurality of conductive patterns 113. In detail, as shown in FIG. 1A, the dielectric layer 111 covers the first layer 100 (i.e., the conductive pads 100a and the conductive pads 100b), and the conductive vias 112 are in physical and electrical contact with the first layer 100 (i.e., the conductive pads 100a and the conductive pads 100b). Further, as shown in FIG. 1A, the first layer 100 (i.e., the conductive pads 100a and the conductive pads 100b) and the conductive vias 112 are embedded in the dielectric layer 111, and each of the conductive vias 112 extends vertically through the dielectric layer 111 along a direction Z to establish electrical connection between the first layer 100 and the conductive patterns 113; and each of the conductive patterns 113 laterally extends over the top surface of the dielectric layer 111 along a direction X perpendicular to the direction Z. In some embodiments, the conductive patterns 113 includes conductive pads, conductive lines, and/or the like. As shown in FIG. 1A, each of the conductive vias 112 is tapered toward the same direction from the conductive patterns 113 to the first layer 100. That is to say, in the cross-sectional view shown from FIG. 1A, along a direction X, the lateral dimension of the surface in contact with the conductive pattern 113 (illustrated as the top surface in FIG. 1A) of the conductive via 112 is larger than the lateral dimension of the surface in contact with the first layer 100 (illustrated as the bottom surface in FIG. 1A) of the conductive via 112. In other words, the lateral dimension of the conductive via 112 decreases from the top of the conductive via 112 to the bottom of the conductive via 112 along the direction Z. However, the disclosure is not limited thereto. In some alternative embodiments, the conductive via 112 may have substantially vertical sidewalls along the direction Z. In other words, an extending direction which the sidewall of the conductive via 112 along with the direction Z may have an angular offset of less than 1°. In some embodiments, the conductive pads 100a and the conductive pads 100b are formed for further electrical connection. Although the first portion P1 is shown as an example having one layer of the second layer 110 including the dielectric layer 111, the conductive vias 112 and the conductive patterns 113, more layers may be formed in the first portion P1.

In some embodiments, the method of forming the first layer 100 of the first portion P1 may include the following steps. First, a seed layer (not shown) is blanketly formed over the carrier C1. The seed layer may be a Ti/Cu bilayer, a copper layer, or other suitable metal layer, and may be deposited using any suitable deposition technique such as physical vapor deposition (PVD), e.g., sputtering, evaporation, etc. Then, a mask pattern (not shown) having openings is formed on and to partially cover the seed layer. The openings of the mask pattern expose the intended location for the subsequently formed conductive pads 100a and conductive pads 100b. The mask pattern may be a patterned photoresist layer, and may be formed by using such as a spin-coating process, lithography and etching processes, or the like. Afterwards, a plating process is performed to form a conductive material layer on the seed layer exposed by the openings of the mask pattern. This is, the conductive material is formed on the seed layer within the openings of the mask pattern. In some embodiments, the plating process may be an electroplating process or an electroless plating process, or the like. In some embodiments, the material of the conductive material layer includes aluminum, titanium, copper, nickel, tungsten, and/or alloys thereof. Subsequently, the mask pattern is removed by a suitable removal process such as ashing, stripping, or the like. After the removal of the mask pattern, portions of the seed layer that were covered by the mask pattern may be removed by any suitable process (e.g., wet etching, dry etching, or the like), and the conductive material may serve as an etch mask during the removal process of the seed layer. The remaining seed layer and the remaining conductive material layer then constitute the conductive pads 100a and the conductive pads 100b.

In some embodiments, the method of forming the second portion 110 of the first portion P1 may include the following steps. After the first layer 100 is formed, the dielectric layer 111 is formed over the carrier C1 to cover the first layer 100. In other words, the conductive pads 100a and the conductive pads 100b are embedded in the dielectric layer 111 at this stage. In some embodiments, the material of the dielectric layer 111 may include a polymer (e.g., polybenzoxazole (PBO), benzocyclobutene (BCB), polyimide, or the like), a nitride, an oxide, an epoxy, a resin, a combination thereof, and/or the like. In some embodiments, the thickness of the dielectric layer 111 is in a range of about 15 μm to about 40 μm. The dielectric layer 111, for example, may be formed by suitable fabrication techniques such as spin-on coating, chemical vapor deposition (CVD), plasma-enhanced chemical vapor deposition (PECVD), or the like. Thereafter, a plurality of openings (not shown) are formed in the dielectric layer 111 to expose the intended location for the subsequently formed conductive vias 112. In some embodiments, the openings may be formed by a photolithography process and an etching process. Subsequently, the step of forming the seed layer, forming the mask pattern having openings, forming the conductive material layer in the openings and removing the mask pattern presented above regarding to the first layer 100 may be repeated to form remaining conductive material layer on the underlying seed layer and expose the underlying seed layer that was covered by the mask pattern. In detail, during the method of forming the second layer 110, the seed layer, the mask pattern, and the conductive material layer are formed similar to those formed during the method of forming the first layer 100, except the differences therebetween at least lie: in the method of forming the second layer 110, the seed layer is blanketly formed on the dielectric layer 111 and formed to extend into the openings of the dielectric layer 111, the openings of the mask pattern expose the intended location for the subsequently formed conductive patterns 113, and the remaining conductive material layer is located over the first layer 100 and the dielectric layer 111. As such, some detailed descriptions thereof are omitted herein, and please refer to the aforesaid descriptions regarding to the first layer 100. After the removal of the mask pattern, portions of the seed layer that are not covered by the remaining conductive material layer may be removed by any suitable process (e.g., wet etching, dry etching, or the like) using the said remaining conductive material layer as an etch mask to obtain the conductive vias 112 and the conductive patterns 113. That is to say, according to the descriptions with respect to forming the first layer 100, those skilled in the art should understand that the remaining seed layer and the remaining conductive material layer constitute the conductive vias 112 and the conductive patterns 113. In other words, the conductive vias 112 and the conductive patterns 113 are formed during the same step.

Continued referring to FIG. 1A, the second portion P2 includes a first layer 120, a second layer 130, a third layer 140, a fourth layer 150, and a fifth layer 160 sequentially overlying the first portion P1, wherein the first layer 120 includes a dielectric layer 121 and a plurality of conductive vias 122, the second layer 130 includes a dielectric layer 131, a plurality of conductive patterns 132 and a plurality of conductive vias 133, the third layer 140 includes a dielectric layer 141, a plurality of conductive patterns 142 and a plurality of conductive vias 143, the fourth layer 150 includes a dielectric layer 151, a plurality of conductive patterns 152 and a plurality of conductive vias 153, and the fifth layer 160 includes a dielectric layer 161, a plurality of conductive patterns 162 and a plurality of conductive vias 163. Although the second portion P2 is shown as an example having five layers (i.e., the first layer 120, the second layer 130, the third layer 140, the fourth layer 150, and the fifth layer 160), more (or fewer) layers may be formed in the second portion P2.

In detail, as shown in FIG. 1A, the conductive vias 122 are embedded in the dielectric layer 121, and each of the conductive vias 122 extends vertically through the dielectric layer 121 along the direction Z to establish electrical connection between the conductive patterns 113 of the second layer 110 in the first portion P1 and the conductive patterns 132 of the second layer 130 in the second portion P2. That is to say, the conductive vias 122 render the electrical connection between the first portion P1 and the second portion P2. Further, as shown in FIG. 1A, the conductive vias 133 are embedded in the dielectric layer 131, and each of the conductive vias 133 extends vertically through the dielectric layer 131 along the direction Z to establish electrical connection between the conductive patterns 132 of the second layer 130 and the conductive patterns 142 of the third layer 140; and each of the conductive patterns 132 laterally extends over the top surface of the dielectric layer 121 along the direction X. Similarly, as shown in FIG. 1A, the conductive vias 143 are embedded in the dielectric layer 141, and each of the conductive vias 143 extends vertically through the dielectric layer 141 along the direction Z to establish electrical connection between the conductive patterns 142 of the second layer 140 and the conductive patterns 152 of the third layer 150; each of the conductive patterns 142 laterally extends over the top surface of the dielectric layer 131 along the direction X; the conductive vias 153 are embedded in the dielectric layer 151, and each of the conductive vias 153 extends vertically through the dielectric layer 151 along the direction Z to establish electrical connection between the conductive patterns 152 of the second layer 150 and the conductive patterns 162 of the third layer 160; and each of the conductive patterns 152 laterally extends over the top surface of the dielectric layer 141 along the direction X. Further, as shown in FIG. 1A, the conductive vias 163 are embedded in the dielectric layer 161, and each of the conductive vias 163 extends vertically through the dielectric layer 161 along the direction Z to establish electrical connection between the conductive patterns 162 of the second layer 160 and the conductive patterns 171 of the first layer 170 in the third portion P3 (described hereinafter); each of the conductive patterns 162 laterally extends over the top surface of the dielectric layer 151 along the direction X. That is to say, the conductive vias 163 render the electrical connection between the second portion P2 and the third portion P3.

In some embodiments, each of the conductive patterns 132, the conductive patterns 142, the conductive patterns 152 and the conductive patterns 162 includes conductive pads, conductive lines, and/or the like. As shown in FIG. 1A, each of the conductive vias 122, the conductive vias 133, the conductive vias 143, the conductive vias 153 and the conductive vias 163 has substantially vertical sidewalls along the direction Z. In other words, an extending direction which the sidewall of the conductive via 122, the conductive via 133, the conductive via 143, the conductive via 153 or the conductive via 163 along with the direction Z may have an angular offset of less than 1°. However, the disclosure is not limited thereto. In some alternative embodiments, a reentrant profile with an undercut may be observed in a lower sidewall of the conductive via 122, the conductive via 133, the conductive via 143, the conductive via 153 or the conductive via 163.

In some embodiments, the method of forming the first layer 120 of the second portion P2 may include the following steps. First, the conductive vias 122 are formed on the remaining conductive material layer used for forming the conductive vias 112 and the conductive patterns 113 of the first portion P1. In detail, the method of forming the conductive vias 122 of the second portion P2 may include the following steps. First, a mask pattern (not shown) having openings is formed over the remaining conductive material layer used for forming the conductive vias 112 and the conductive patterns 113 and the seed layer under the said remaining conductive material layer to partially cover the said remaining conductive material layer. The openings of the mask pattern expose the intended location for the subsequently formed conductive vias 122. The mask pattern may be a patterned photoresist layer, and may be formed by using such as a spin-coating process, lithography and etching processes, or the like. Next, the conductive material layer is formed on the said remaining conductive material layer within the openings of the mask pattern by a plating process such as an electroplating process, an electroless plating process, or other suitable deposition process. In some embodiments, the material of the conductive material layer includes aluminum, titanium, copper, nickel, tungsten, and/or alloys thereof. Subsequently, the mask pattern is removed to render the conductive vias 122 by a suitable removal process such as ashing, stripping, or the like.

It is noted that since the seed layer under the said remaining conductive material layer used for forming the conductive vias 112 and the conductive patterns 113 is not removed yet during the formation of the conductive vias 122, the plating process of the conductive vias 122 shares the same seed layer with the plating process of the conductive vias 112 and the conductive patterns 113. That is, the seed layer blanketly formed over the dielectric layer 111 may be utilized for plating for the conductive vias 112 and the conductive patterns 113 in the first portion P1 and the conductive vias 122 in the second portion P2. As a result, the conductive vias 122 are physically in contact with the conductive patterns 113. In detail, the conductive vias 122 are directly in contact with the conductive patterns 113. From another point of view, the conductive vias 122 are free of seed layer, and no seed layer exists between the conductive patterns 113 and the conductive vias 122. Further, it is noted that since the seed layer under the said remaining conductive material layer used for forming the conductive vias 112 and the conductive patterns 113 is removed after the conductive vias 122 are formed (i.e., after the mask pattern used for forming the conductive vias 122 is removed), the conductive vias 112 and the conductive patterns 113 each constituted by the remaining seed layer and the remaining conductive material layer are formed after the conductive vias 122 are formed.

After forming the conductive vias 122, the dielectric layer 121 is formed over the carrier C1 to cover the conductive patterns 113 and laterally cover the conductive vias 122. In detail, the method of forming the dielectric layer 121 of the second portion P2 may include the following steps. First, a dielectric material layer is formed on the conductive patterns 113 and the dielectric layer 111 by a process such as lamination, spin-coating, CVD, a combination thereof, etc. The material of the dielectric material layer may be or may include polybenzoxazole (PBO), polyimide (PI), benzocyclobutene (BCB), prepreg, Ajinomoto build-up film (ABF), an oxide (e.g., silicon oxide), a nitride (e.g., silicon nitride), a photosensitive polymer material, a combination thereof, and/or the like. Thereafter, the dielectric material layer is planarized, such as by a chemical mechanical polish (CMP) or a mechanical grinding, to form the dielectric layer 121. In some embodiments, as shown in FIG. 1A, the illustrated top surface of the dielectric layer 121 is substantially leveled with the illustrated top surfaces of the conductive vias 122. In some embodiments, the thickness of the dielectric layer 121 is in a range of about 15 μm to about 50 μm. In some embodiments, the material of the dielectric layer 121 in the second portion P2 is different from the material of the dielectric layer 111 in the first portion P1. However, the disclosure is not limited thereto. The material of the dielectric layer 121 in the second portion P2 may be the same as the material of the dielectric layer 111 in the first portion P1 depending on product and process requirements.

In some embodiments, the method of forming the second layer 130 of the second portion P2 may include the following steps. First, the step of forming the seed layer, forming the mask pattern having openings, forming the conductive material layer in the openings and removing the mask pattern presented above regarding to the first layer 100 may be repeated to form the remaining conductive material layer on the underlying seed layer and expose the underlying seed layer that was covered by the mask pattern. In detail, during the method of forming the second layer 130, the seed layer, the mask pattern, and the conductive material layer are formed similar to those formed during the method of forming the first layer 100, except the differences therebetween at least lie: in the method of forming the second layer 130, the seed layer is blanketly formed on the dielectric layer 121 and the conductive vias 122, the openings of the mask pattern expose the intended location for the subsequently formed conductive patterns 132, and the remaining conductive material layer is located over the dielectric layer 121 and the conductive vias 122. As such, some detailed descriptions thereof are omitted herein, and please refer to the aforesaid descriptions regarding to the first layer 100. Next, after the removal of the mask pattern, the conductive vias 133 and the conductive patterns 132 are sequentially formed on the dielectric layer 121 and the conductive vias 122. In detail, the conductive vias 133 are formed using the processes similar to the formation of the conductive vias 122, and the conductive patterns 132 are formed using the processes similar to the formation of the conductive vias 112 and the conductive patterns 113. As such, some detailed descriptions of the conductive vias 133 and the conductive patterns 132 are omitted herein, and please refer to the aforesaid descriptions regarding to the conductive vias 122, the conductive vias 112 and the conductive patterns 113. Further, it is noted that the plating process of the conductive vias 133 shares the same seed layer with the plating process of the conductive patterns 132. That is, the seed layer blanketly formed over the dielectric layer 121 and the conductive vias 122 may be utilized for plating for the conductive vias 133 and the conductive patterns 132. As a result, the conductive vias 133 are physically in contact with the conductive patterns 132. In detail, the conductive vias 133 are directly in contact with the conductive patterns 132. From another point of view, the conductive vias 133 are free of seed layer, and no seed layer exists between the conductive patterns 132 and the conductive vias 133. Afterwards, the dielectric layer 131 is formed on the dielectric layer 121 to cover the conductive patterns 132 and laterally cover the conductive vias 133 using the processes similar to the formation of the dielectric layer 121. As such, some detailed descriptions thereof are omitted herein, and please refer to the aforesaid descriptions regarding to the dielectric layer 121. The material of the dielectric layer 131 may be the same as or different from the material of the dielectric layer 121 depending on product and process requirements.

Continued referring to FIG. 1A, after the second layer 130 is formed, the third layer 140, the fourth layer 150, and the fifth layer 160 are sequentially formed using the processes similar to the formation of the second layer 130. In detail, the conductive vias 143, the conductive vias 153 and the conductive vias 163 are respectively formed by processes similar to those used to form the conductive vias 133, and the conductive patterns 142, the conductive patterns 152 and the conductive patterns 162 are respectively formed by processes similar to those used to form the conductive patterns 132, except the differences therebetween at least lie: the plating process of the conductive vias 143 shares the same seed layer with the plating process of the conductive patterns 142, the plating process of the conductive vias 153 shares the same seed layer with the plating process of the conductive patterns 152, and the plating process of the conductive vias 163 shares the same seed layer with the plating process of the conductive patterns 162. That is, the conductive vias 143, the conductive vias 153 and the conductive vias 163 are respectively free of seed layer; no seed layer exists between the conductive patterns 142 and the conductive vias 143, between the conductive patterns 152 and the conductive vias 153 and between the conductive patterns 162 and the conductive vias 163; and the conductive vias 143, the conductive vias 153 and the conductive vias 163 are respectively directly in contact with the conductive patterns 142, the conductive patterns 152 and the conductive patterns 162. As such, some detailed descriptions of the conductive vias 143, the conductive vias 153, the conductive vias 163, the conductive patterns 142, the conductive patterns 152 and the conductive patterns 162 are omitted herein, and please refer to the aforesaid descriptions regarding to the conductive vias 133 and the conductive patterns 132.

Continued referring to FIG. 1A, the third portion P3 includes a first layer 170 and a second layer 180 overlying the first layer 170, the first layer 170 includes a plurality of conductive patterns 171, and the second layer 180 includes a dielectric layer 181, a plurality of conductive vias 182 and a plurality of conductive patterns 183. In detail, as shown in FIG. 1A, the dielectric layer 181 covers the first layer 170 (i.e., the conductive patterns 171), and the conductive vias 182 are in physical and electrical contact with the first layer 170 (i.e., the conductive patterns 171). Further, as shown in FIG. 1A, the conductive vias 182 are embedded in the dielectric layer 181, and each of the conductive vias 182 extends vertically through the dielectric layer 181 along the direction Z to establish electrical connection between the first layer 170 and the conductive patterns 183; and each of the conductive patterns 183 laterally extends over the top surface of the dielectric layer 181 along the direction X. In some embodiments, the conductive patterns 183 are conductive pads for further electrical connection. As shown in FIG. 1A, each of the conductive vias 182 is tapered toward the same direction from the conductive patterns 183 to the first layer 170. That is, in the cross-sectional view shown from FIG. 1A, along the direction X, the lateral dimension of the surface in contact with the conductive pattern 183 (illustrated as the top surface in FIG. 1A) of the conductive via 182 is larger than the lateral dimension of the surface in contact with the first layer 170 (illustrated as the bottom surface in FIG. 1A) of the conductive via 182. In other words, the lateral dimension of the conductive via 182 decreases from the top of the conductive via 182 to the bottom of the conductive via 182 along the direction Z. However, the disclosure is not limited thereto. In some alternative embodiments, the conductive via 182 may have substantially vertical sidewalls along the direction Z. In other words, an extending direction which the sidewall of the conductive via 182 along with the direction Z may have an angular offset of less than 1°. Although the third portion P3 is shown as an example having one layer of the second layer 180 including the dielectric layer 181, the conductive vias 182 and the conductive patterns 183, more layers may be formed in the third portion P3. In embodiments where the third portion P3 has more than one second layer 180, the conductive patterns 183 in the outermost second layer 180 are conductive pads for further electrical connection, and the conductive patterns 183 in the other second layer(s) 180 include conductive pads, conductive lines, and/or the like.

In some embodiments, the conductive patterns 171 of the first layer 170 in the third portion P3 are formed using the processes similar to the formation of the conductive pads 100a and the conductive pads 100b of the first layer 100 in the first portion P1, except the differences therebetween at least lie: the conductive patterns 171 constituted by the remaining seed layer and the remaining conductive material layer are formed on and in physical and electrical contact with the conductive vias 163. As such, some detailed descriptions thereof are omitted herein, and please refer to the aforesaid descriptions regarding to the conductive pads 100a and the conductive pads 100b.

In some embodiments, the method of forming the second layer 180 of the third portion P3 may include the following steps. After the first layer 170 is formed, the dielectric layer 181 having openings (not shown) is formed using the processes similar to the formation of the dielectric layer 111 of the second layer 110 in the first portion P1, except the differences therebetween at least lie: the dielectric layer 181 is formed on the conductive patterns 171, and the openings of the dielectric layer 181 are formed to expose the intended location for the subsequently formed conductive vias 182. As such, some detailed descriptions thereof are omitted herein, and please refer to the aforesaid descriptions regarding to the dielectric layer 111. In some embodiments, the thickness of the dielectric layer 181 is in a range of about 5 μm to about 20 μm. Next, the conductive vias 182 and the conductive patterns 183 are formed using the processes similar to the formation of the conductive vias 112 and the conductive patterns 113 in the first portion P1, except the differences therebetween at least lie: after the removal of the mask pattern, portions of the seed layer that were covered by the mask pattern are subsequently removed to render the conductive vias 182 and the conductive patterns 183 together on the first layer 170. As such, some detailed descriptions of the conductive vias 182 and the conductive patterns 183 are omitted herein, and please refer to the aforesaid descriptions regarding to the conductive vias 112 and the conductive patterns 113.

Still referring to FIG. 1A, the redistribution structure RDL has a first region R1 and a second region R2 surrounding the first region R1. In some embodiments, the conductive pads 100a of the first portion P1 are located in the first region R1, while the conductive pads 100b of the first portion P1 are located in the second region R2. In some embodiments, the first region R1 is referred to as a testing region, while the second region R2 is referred to as a device region. As such, in some embodiments, the conductive pads 100a are referred to as testing pads able to transmit testing signals, while the conductive pads 100b are able to bond and couple to devices (e.g., passive devices 500 in FIG. 1G).

Referring to FIG. 1B, after the redistribution structure RDL is formed over the carrier C1, the redistribution structure RDL is flipped (i.e., turned upside down) and placed on a carrier C2 for further processing. In some embodiments, as shown in FIG. 1B, the conductive patterns 183 and the dielectric layer 181 of the third portion P3 are boned to the carrier C2 through an adhesive layer AD. In some embodiments, the adhesive layer AD includes a die attach film (DAF). However, the disclosure is not limited thereto. In some alternative embodiments, other materials may be adapted as the adhesive layer AD as long as the said materials are able to strengthen the adhesion between the carrier C2 and the conductive patterns 183 along with the dielectric layer 181. In certain embodiments, the carrier C2 is a glass carrier, a metal plate, a plastic supporting board or the like, but other suitable substrate materials may be used as long as the materials are able to withstand the subsequent steps of the process. Subsequently, the carrier C1 is de-bonded and is separated from the redistribution structure RDL to expose the surfaces Sa of the conductive pads 100a (illustrated as the top surfaces in FIG. 1B) and the surfaces Sb of the conductive pads 100b (illustrated as the top surfaces in FIG. 1B) and the surface S111 of the dielectric layer 111 (illustrated as the top surface in FIG. 1B). It is noted that since the carrier C1 is planar, the first layer 100 first formed over the carrier C1 and the dielectric layer 111 formed to cover the first layer 100 have a high degree of coplanarity. That is to say, the de-bonded surface of the redistribution structure RDL provides a high degree of coplanarity as smooth as the surface of the carrier C1. In other words, as shown in FIG. 1B, the surfaces Sa of the conductive pads 100a, the surfaces Sb of the conductive pads 100b and the surface S111 of the dielectric layer 111 are substantially flush and coplanar with each other.

Referring to FIG. 1C, an electroless plating process EP is performed to form multiple protective patterns 200 on the surfaces Sa of the conductive pads 100a and the surfaces Sb of the conductive pads 100b. In some embodiments, during the electroless plating process EP, the material of the protective pattern 200 is selected to have high reactivity with metal materials. Examples of the said material of the protective patterns 200 include Ti, Ta, TiN, TaN, Ni, NiV, NiP Cr, Au, Pt, or a combination thereof. That is, during the electroless plating process EP, compared with the surface S111 of the dielectric layer 111, the surfaces Sa of the conductive pads 100a and the surfaces Sb of the conductive pads 100b are highly prone to react and bond with the protective patterns 200. In other words, the electroless plating process EP is used to selectively cover up the entirety of the surfaces Sa of the conductive pads 100a and the entirety of the surfaces Sb of the conductive pads 100b without covering the surface S111 of the dielectric layer 111. From another point of view, as shown in FIG. 1B, the protective patterns 200 are in directly contact with the conductive pads 100a and the conductive pads 100b. Since the conductive pads 100a and the conductive pads 100b are separated from each other, the protective patterns 200 formed corresponding to the conductive pads 100a and the conductive pads 100b are separated from each other.

As mentioned above, the surfaces Sa of the conductive pads 100a and the surfaces Sb of the conductive pads 100b are substantially flush and coplanar with the surface S111 of the dielectric layer 111, and thus the protective patterns 200 disposed on the surfaces Sa of the conductive pads 100a and the surfaces Sb of the conductive pads 100b are protruded from the surface S111 of the dielectric layer 111. That is, along the direction Z, the surface S200 of the protective pattern 200 is located at a level height higher than the surface S111 of the dielectric layer 111. In some embodiments, as shown in FIG. 1B, each of the protective patterns 200 is a single layer. However, the disclosure is not limited thereto. In some alternative embodiments, each of the protective patterns 200 may be a multilayer structure. In some embodiments, the thickness of the protective pattern 200 is in a range of about 0.5 μm to about 10 μm. In some embodiments, the hardness of the protective pattern 200 is greater than the hardness of the conductive pads 100a and the hardness of the conductive pads 100b. In some embodiments, the hardness of the protective pattern 200 is selected to be able to withstand the repeated probing contact by probing tips (e.g., probing tips 602 in FIG. 1G) of a probe head (e.g., probe head 600 in FIG. 1G), such that the conductive pads 100a and the conductive pads 100b covered by the protective patterns 200 are protected. Further, it is noted that by arranging the protective patterns 200 to cover up the surfaces Sa of the conductive pads 100a and the surfaces Sb of the conductive pads 100b exposed by the dielectric layer 111, the oxidation resistance of the conductive pads 100a and the conductive pads 100b is improved.

Referring to FIG. 1D, after the formation of the protective patterns 200, the structure illustrated in FIG. 1C is flipped (i.e., turned upside down) and placed on a tape frame 70 for further processing. In some embodiments, as shown in FIG. 1D, the protective patterns 200 and the dielectric layer 111 are attached onto the tape frame 70. Subsequently, the carrier C2 is de-bonded and is separated from the conductive patterns 183 and the dielectric layer 181 to expose the conductive patterns 183. Next, a plurality of bonding elements 190 are formed on the conductive patterns 183. In some embodiments, bonding elements 190 are formed by: forming a layer of solder on the respective conductive pattern 183 through evaporation, electroplating, printing, solder transfer, ball placement, and/or the like; and performing a reflow process to shape the solder material into the desired bump shapes. The bonding elements 190 may be (or include) BGA connectors, solder balls, C4 bumps, micro bumps, ENEPIG bumps, and/or the like. The bonding elements 190 are electrically connected to the redistribution structure RDL through the conductive patterns 183. In some embodiments, the diameter of the bonding element 190 is in a range of about 150 μm to about 350 μm.

Referring to FIG. 1E, a substrate component 300 is provided. The substrate component 300 may be (or include) an organic substrate, a ceramic substrate, a silicon substrate, or the like. The substrate component 300 may include active and passive devices (not shown), or may be free from either active devices, passive devices, or both. Utilizing the substrate component 300 has the advantage of having the substrate component 300 being manufactured in a separate process. In some embodiments, because the substrate component 300 is formed in a separate process, the substrate component 300 may be individually or batch tested, validated, and/or verified prior to coupling the substrate component 300 to the redistribution structure RDL. Before being coupled to the redistribution structure RDL, the substrate component 300 may be processed according to applicable manufacturing processes to form redistribution structures in the substrate component 300.

In some embodiments, the substrate component 300 is a core substrate which includes a core layer 321. The core layer 321 may be formed of organic and/or inorganic materials. For example, the core layer 321 includes one or more layers of glass fiber, resin, filler, prepreg, epoxy, silica filler, Ajinomoto Buildup Film (ABF), polyimide, molding compound, other materials, and/or combinations thereof. In some embodiments, the core layer 321 includes one or more passive components (not shown) embedded therein. The core layer 321 may include other materials or components. Alternatively, the substrate component 300 is a coreless substrate. The substrate component 300 may include through core vias 322 extending through the core layer 321 for providing vertical electrical connections between two opposing sides (321a and 321b) of the core layer 321. In some embodiments, the through core vias 322 are hollow through vias having centers that are filled with an insulating material. In some embodiments, the through core vias 322 are solid conductive pillars.

With continued reference to FIG. 1E, the substrate component 300 includes a first build-up structure 324A and a second build-up structure 324B electrically coupled to each other through the through core vias 322, and fan-in/fan-out electrical signals. In some embodiment, the formation of the first build-up structure 324A includes forming dielectric layers 324A2 and forming conductive patterns 324A1 in/on the dielectric layers 324A2, where the dielectric layers 324A2 and the conductive patterns 324A1 are alternately stacked over the first side 321a of the core layer 321. Similarly, the formation of the second build-up structure 324B may include forming dielectric layers 324B2 and conductive patterns 324B1 in/on the dielectric layers 324B2, where the dielectric layers 324B2 and the conductive patterns 324B1 are alternately stacked over the second side 321b of the core layer 321. More or fewer dielectric layers and conductive patterns may be formed in the first and second build-up structures 324A and 324B than shown in FIG. 1E.

The conductive patterns 324A1 and 324B1 may each include conductive vias, conductive lines, conductive pads, and/or the like, and may include conductive material(s) such as copper, gold, tungsten, aluminum, silver, gold, alloy, a combination thereof, and/or the like. In some embodiments, the conductive vias of the conductive patterns 324A1 and 324B1 are tapered in opposing directions. For example, the conductive vias of the conductive patterns 324A1 are tapered from the first build-up structure 324A toward the second build-up structure 324B, and the conductive vias of the conductive patterns 324B1 are tapered from the second build-up structure 324B toward the first build-up structure 324A. The dielectric layers 324A2 and 324B2 may include ABF, prepreg, resin coated copper foil (RCC), polyimide, photo-image-dielectric (PID), solder resist material, molding compound, a combination thereof, and/or the like, and may be formed by a lamination process, a coating process, or the like.

With continued reference to FIG. 1E, the outermost layers of the conductive patterns 324A1 and 324B1 may each, respectively, include under-bump metallization (UBM) pads 324AP and 324BP for external connections. The outermost layers of the dielectric layers 324A2 and 324B2 may each, respectively, include resist sublayers 324AR and 324BR covering the corresponding UBM pads 324AP and 324BP. For example, the resist sublayer 324AR laterally covers the respective UBM pad 324AP and may (or may not) extend to partially cover the surface of the respective UBM pad 324AP which faces toward the redistribution structure RDL (illustrated as the bottom surface in FIG. 1E). The resist sublayer 324BR may laterally cover the respective UBM pad 324BP and may (or may not) extend to partially cover the surface of the respective UBM pad 324BP which faces away from the redistribution structure RDL (illustrated as the top surface in FIG. 1E). In some embodiments, along a direction X, the lateral dimension D1 of the conductive patterns 183 of the redistribution structure RDL is less than the lateral dimension D2 of the UBM pads 324AP of the substate component 300.

In some embodiments, the substrate component 300 further includes bonding elements 324A3 formed on the UBM pads 324AP with a one-to-one correspondence. The bonding elements 324A3 and the bonding elements 190 may be of the same (or similar) material. The bonding elements 324A3 may be formed by: forming a layer of solder on the respective UBM pad 324AP through evaporation, electroplating, printing, solder transfer, ball placement, or the like; and performing a reflow process to shape the solder material into the desired bump shapes. The bonding elements 324A3 may be (or include) BGA connectors, solder balls, C4 bumps, micro bumps, ENEPIG bumps, and/or the like.

Referring to FIG. 1F and with reference to FIG. 1E, after contacting the bonding elements 324A3 of the substrate component 300 with the bonding elements 190, a reflow process may be performed to bond the substrate component 300 with the redistribution structure RDL. That is, the first build-up structure 324A is located nearer to the redistribution structure RDL than the second build-up structure 324B. For example, the bonding elements 324A3 and 190 are heated such that the bonding elements 324A3 and the corresponding bonding elements 190 bond with each other and form a physical and electrical bond. For example, the reflow process reflows the bonding elements 324A3 and 190, and then the bonding elements 324A3 and 190 become conductive joints 12 (e.g., solder joints). In some embodiments, pressure may also be applied to the bonding elements 324A3 and 190 downwardly to the tape frame 70. In some embodiments, the reflow process is performed at a temperature suitable to melt the solder material, such as between about 170° C. and about 250° C. The reflow process may be performed for a time sufficient to cure the bonding elements 324A3 and 190, such as between about 1 minute to about 3 minutes. The temperature and the duration of the reflow may be determined by the composition of the bonding elements 324A3 and 190, and other temperature profiles and duration are also possible. In some embodiments, as shown in FIG. 1F, the conductive joint 12 substantially covers the entirety of the illustrated bottom surface of the UBM pad 324AP which is exposed by the resist sublayer 324AR, and substantially also covers the entireties of the surface (illustrated as the top surface in FIG. 1F) and the sidewall of the conductive pattern 183 which is protruded from the dielectric layer 181. Although the substrate component 300 is bonded with the redistribution structure RDL by forming the bonding elements 190 on the conductive patterns 183 and forming the bonding elements 324A3 on the UBM pads 324AP, the disclosure is not limited thereto. In some alternative embodiments, before bonding the substrate component 300 and the redistribution structure RDL, only the bonding elements 190 is formed on the conductive patterns 183, or only the bonding elements 324A3 is formed on the UBM pads 324AP.

With continued reference to FIG. 1F, an insulating encapsulation 400 is formed on the redistribution structure RDL to encapsulate the substrate component 300. The insulating encapsulation 400 may be (or include) molding compound, molded underfill, polymer such as polyimide, PBO, BCB, ABF, or other suitable encapsulating materials, and may be formed compression molding, transfer molding, or other suitable deposition methods. For example, an insulating material is formed over the tape frame 70, such that the substrate component 300 over the tape frame 70 may be buried or covered. In some embodiments, the insulating encapsulation 400 includes fillers (not shown). The insulating encapsulation 400 may be applied in liquid or semi-liquid form and then subsequently cured. A planarization process and/or a cleaning process may be performed, if necessary, on the insulating material to form the insulating encapsulation 400 that accessibly exposes the UBM pads 324BP of the substrate component 300. In some embodiments, the planarization process is omitted, if the UBM pads 324BP are already exposed. Other processes may be used to achieve a similar result.

The insulating encapsulation 400 may cover at least a portion of the sidewall 300s of the substrate component 300. In some embodiments, the insulating encapsulation 400 covers the entirety of the sidewall 300s of the substrate component 300, where the sidewall 300s includes outer sidewalls of the core layer 321 and the first and second build-up structures 3240A and 324B. The insulating encapsulation 400 may also be formed in the gap between and the redistribution structure RDL and the substrate component 300 to securely bond the associated elements and provide structural support and environmental protection. For example, the insulating encapsulation 400 surrounds the conductive joints 12, and is in contact with the exposed surfaces of dielectric layer 181 of the redistribution structure RDL and the resist sublayer 324AR of the substrate component 300.

Referring to FIG. 1G, after forming the insulating encapsulation 400, a singulation process is performed over the tape frame 70 to form individual and separated integrated substrates IS. Although one singulated integrated substrate IS is shown in FIG. 1G, those skilled in the art should understand that plural integrated substrates IS are obtained after the singulation process. For example, the insulating encapsulation 400 and the redistribution structure RDL are cut through to form the integrated substrate IS having a coterminous sidewall 10s, where the coterminous sidewall 10s includes the sidewall 400s of the insulating encapsulation 400 and the sidewall RDLs of the redistribution structure RDL substantially leveled with each other. After the singulation process, the integrated substrate IS may be removed from the tape frame 70 through a de-taping process in order to accessibly expose the protective patterns 200 for further processing. In some embodiments, the singulation process typically involves dicing with a rotating blade or a laser beam. In other words, the singulation process is, for example, a laser cutting process, a mechanical cutting process, or other suitable processes.

Still referring to FIG. 1G, a plurality of passive devices 500 are bonded to the redistribution structure RDL. Although FIG. 1G illustrates that two passive devices 500 are bonded to the redistribution structure RDL of one integrated substrate IS, it should be noted that the number of the passive devices 500 bonded to the redistribution structure RDL of one integrated substrate IS are not limited thereto, and can be adjusted based on demand and/or design layout. In some embodiments, as shown in FIG. 1G, the passive device 500 is bonded and connected with the protective patterns 200 covering the conductive pads 100b in second region R2 though a plurality of solder regions 502. That is, the passive device 500 is bonded to the redistribution structure RDL at one side that is opposite to the side of the redistribution structure RDL that the substrate component 300 is bonded at. In some embodiments, the solder region 502 includes solder material. In some embodiments, the solder region 502 is made of a conductive material with low resistivity, such as Sn, Pb, Ag, Cu, Ni, Bi, or an alloy thereof. In some embodiments, the solder region 502 is formed through evaporation, electroplating, printing, solder transfer, ball placement, a reflowing process, or combinations thereof. In some embodiments, as shown in FIG. 1G, the solder region 502 substantially covers the entireties of the surface (illustrated as the top surface in FIG. 1G) and the sidewall of the protective pattern 200 which is protruded from the dielectric layer 111. However, the disclosure is not limited thereto. In some alternative embodiments, the solder region 502 may substantially covers only the entirety of the illustrated top surface of the protective pattern 200 which is protruded from the dielectric layer 111. Although FIG. 1G illustrates that a visible interface is formed between the solder region 502 and the protective pattern 200, the disclosure is not limited thereto. In embodiments where the material of the protective pattern 200 is Au, during the process of bonding the passive device 500 with the protective patterns 200 through the solder regions 502, the protective pattern 200 (i.e., Au) is dissolved into the solder regions 502, and thus no visible interface is formed therebetween. In some embodiments, the passive device 500 includes a surface mount device (SMD) or an integrated passive device (IPD) that comprises passive devices such as resistors, inductors, capacitors, fuses, jumpers, combinations of these, or the like.

Still referring to FIG. 1G, a probe head 600 is provided. In some embodiments, as shown in FIG. 1G, the probe head 600 includes a plurality of probing tips 602 for engaging and mating with the protective patterns 200 covering the conductive pads 100a in first region R1, so as to transmit the test signal from a circuit board (e.g., circuit board 700 in FIG. 1H) to a device-under-test (DUT) (not shown). That is, the probing tips 602 of the probe head 600 are in physical and electrical contact with the protective patterns 200 covering the conductive pads 100a for providing signal transmission. In other words, during testing, the probing tips 602 are in directly contact with the protective patterns 200 rather than the underlying conductive pads 100a. In detail, as shown in FIG. 1G, the probe head 600 is arranged on the redistribution structure RDL at one side that is opposite to the side of the redistribution structure RDL that the substrate component 300 is bonded at. From another point of view, the conductive pads 100a can be referred to as testing pads. It is noted that by arranging the protective patterns 200 having greater hardness than the conductive pads 100a on the surfaces Sa of the conductive pads 100a facing toward the probing tips 602, the protective patterns 200 can protect the conductive pads 100a from repeated probing contact. Therefore, the probing endurance of the resulting package structure 10 is improved. Further, it is noted that the surfaces Sa of the conductive pads 100a and the surfaces Sb of the conductive pads 100b have a high degree of coplanarity due to the manufacturing process of the redistribution structure RDL, and thus the improved electrical performance between the probing tips 602 and the protective patterns 200 covering the conductive pads 100a the protective patterns 200 covering the conductive pads 100a is achieved.

As shown in FIG. 1G, the probe head 600 further includes a plurality of probing tips 604 for engaging and mating with testing pads on the DUT (not shown) for testing. The probing tips 604 may be arranged based on the specific IC design of the DUT. For example, the probing tips 604 have a pitch that matches the pitch of test pads on the DUT. In certain embodiments, the pitch of the probing tips 604 is in a range of about 20 μm to about 200 μm. In some embodiments, the probing tips 604 and the probing tips 602 are referred to as needle tips. In some embodiments, the passive devices 500 are bonded to passive devices 500 are bonded to the redistribution structure RDL before providing the probe head 600. In some alternative embodiments, the passive devices 500 are bonded to passive devices 500 are bonded to the redistribution structure RDL after providing the probe head 600.

Referring to FIG. 1H, after the passive devices 500 and the probe head 600 are disposed over the redistribution structure RDL, the integrated substrate IS is mounted to a circuit board 700 to form the package structure 10. In some embodiments, as shown in FIG. 1H, the integrated substrate IS is bonded and electrically connected with the circuit board 700 though a plurality of external terminals 11 for electrical connections to other external devices or electronic components. In detail, the external terminals 11 are formed on the UBM pads 324BP of the substrate component 300. As such, the substrate component 300 is located between the circuit board 700 and the redistribution structure RDL. The external terminals 11 may include a conductive material such as solder, copper, aluminum, gold, nickel, silver, palladium, tin, alloy, the like, or a combination thereof. The external terminals 11 may be BGA connectors, solder balls, metal pillars, C4 bumps, micro bumps, and/or the like. The circuit board 700 may be or may include a printed circuit board (PCB), a system board, or the like.

The critical dimension of the external terminals 11 may be greater than the critical dimension of the conductive joints 12. By way of example and not limitation, the critical dimension of the respective external terminal 11 is about 500 μm, and the critical dimension of the respective conductive joint 12 is about 250 μm. In a given area, the density of the external terminals 11 may be less than that of the conductive joints 12. For example, the pitch of the adjacent external terminals 11 is greater than the pitch of the adjacent conductive joints 12. By way of example and not limitation, the pitch of the adjacent external terminals 11 is about 1000 μm, and the pitch of the adjacent conductive joints 12 is about 500 μm. Other values are fully intended to be included within the scope of the disclosure.

In some embodiments, the package structure 10 including the integrated substrate IS, the probe head 600 electrically coupled with the redistribution structure RDL of the integrated substrate IS, and the circuit board 700 electrically coupled with the substrate component 300 of the integrated substrate IS is referred to as a probe card, and the integrated substrate IS including the redistribution structure RDL and the substrate component 300 electrically coupled with each other is referred to as a space transformer.

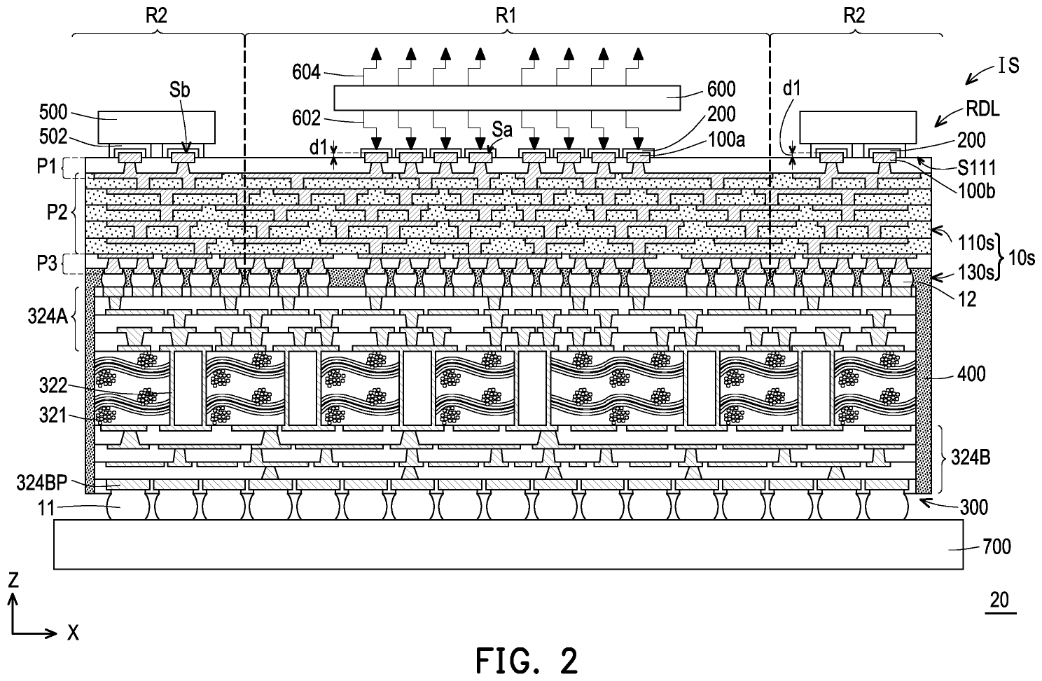

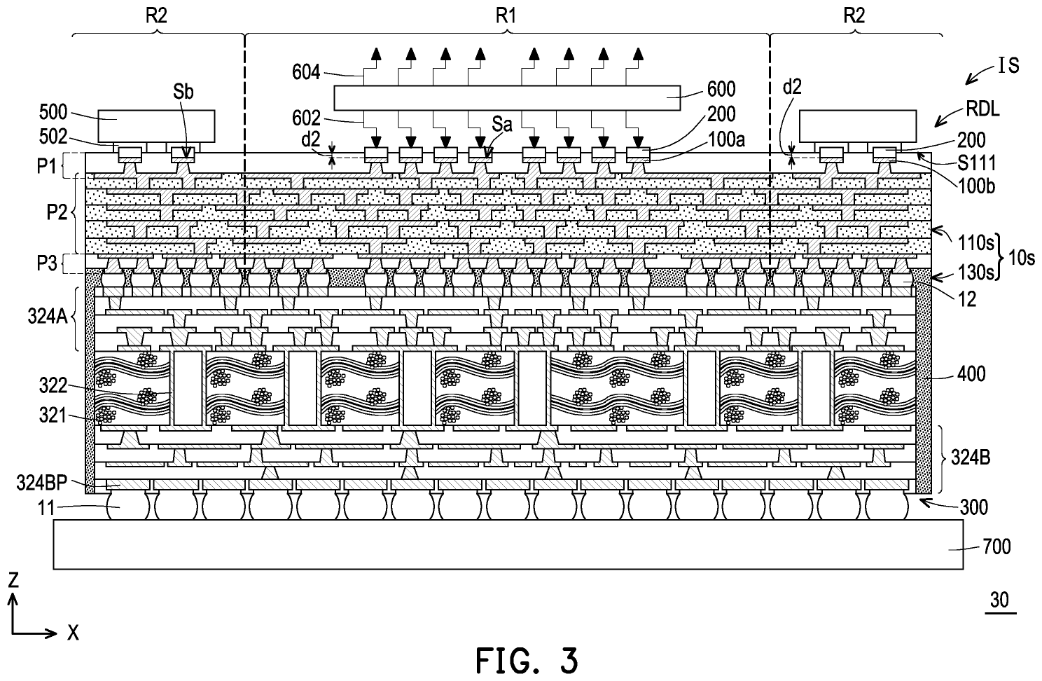

As shown in FIG. 1H, in the package structure 10, the surface S111 of the dielectric layer 111 is located at the same level height as the surfaces Sa of the conductive pads 100a and the surfaces Sb of the conductive pads 100b. However, the disclosure is not limited thereto. In some alternative embodiments, the surface S111 of the dielectric layer 111 may be located at a level height higher than or lower than that of the surfaces Sa of the conductive pads 100a and the surfaces Sb of the conductive pads 100b. Hereinafter, other embodiments will be described with reference to FIG. 2 and FIG. 3.

FIG. 2 is a schematic cross-sectional view illustrating a package structure in accordance with some alternative embodiments of the disclosure. The package structure 20 illustrated in FIG. 2 is similar to the package structure 10 illustrated in FIG. 1H, hence the same reference numerals are used to refer to the same or liked parts, and its detailed description will be omitted herein. The main difference between the package structure 20 and the package structure 10 lies in that in the package structure 20, the surface S111 of the dielectric layer 111 is located at a level height lower than that of the surfaces Sa of the conductive pads 100a and the surfaces Sb of the conductive pads 100b. In some embodiments, the distance d1 between the surface S111 of the dielectric layer 111 and the surfaces Sa of the conductive pads 100a or the surfaces Sb of the conductive pads 100b along the direction Z is less than about 5 μm. Furthermore, according to the descriptions with respect to FIGS. 1A-1H, those skilled in the art should understand that the package structure 20 may be manufactured following the method described above in conjunction with FIGS. 1A-1H, except that after the carrier C1 is de-bonded from the redistribution structure RDL and before the protective patterns 200 are formed, the dielectric layer 111 is partially removed to expose the sidewalls of the conductive pads 100a and the conductive pads 100b. That is, in the package structure 20, each of the conductive pads 100a and the conductive pads 100b is partially laterally covered by the dielectric layer 111. In detail, as shown in FIG. 2, the dielectric layer 111 is selectively removed, while the conductive pads 100a and the conductive pads 100b are intact and not damaged. That is to say, during the removal process of the dielectric layer 111, the material of the conductive pad 100a or the conductive pad 100b has sufficient removing selectivity with respect to the material of the dielectric layer 111. In some embodiments, the dielectric layer 111 is removed by a suitable removal process such as ashing, or the like. From another point of view, since the sidewalls of the conductive pads 100a and the conductive pads 100b are exposed after the dielectric layer 111 is partially removed, during the electroless plating process EP, each of the protective patterns 200 is also formed on the exposed sidewall of the corresponding conductive pad 100a or conductive pad 100b. That is, each of the protective patterns 200 is formed on the protruded portion of the corresponding conductive pad 100a or conductive pad 100b from the surface S111 of the dielectric layer 111.

FIG. 3 is a schematic cross-sectional view illustrating a package structure in accordance with some alternative embodiments of the disclosure. The package structure 30 illustrated in FIG. 3 is similar to the package structure 10 illustrated in FIG. 1H, hence the same reference numerals are used to refer to the same or liked parts, and its detailed description will be omitted herein. The main difference between the package structure 30 and the package structure 10 lies in that in the package structure 30, the surface S111 of the dielectric layer 111 is located at a level height higher than that of the surfaces Sa of the conductive pads 100a and the surfaces Sb of the conductive pads 100b. In some embodiments, the distance d2 between the surface S111 of the dielectric layer 111 and the surfaces Sa of the conductive pads 100a or the surfaces Sb of the conductive pads 100b along the direction Z is less than about 5 μm. Furthermore, according to the descriptions with respect to FIGS. 1A-1H, those skilled in the art should understand that the package structure 20 may be manufactured following the method described above in conjunction with FIGS. 1A-1H, except that after the carrier C1 is de-bonded from the redistribution structure RDL and before the protective patterns 200 are formed, each of the conductive pads 100a and the conductive pads 100b is partially removed to form recesses. In detail, as shown in FIG. 3, each of the conductive pads 100a and the conductive pads 100b is selectively removed, while the dielectric layer 111 is intact and not damaged. That is to say, during the removal process of the conductive pads 100a and the conductive pads 100b, the material of the dielectric layer 111 has sufficient removing selectivity with respect to the material of the conductive pad 100a or the conductive pad 100b. In some embodiments, each of the conductive pads 100a and the conductive pads 100b is removed by a suitable removal process such as etching (e.g., wet etching), or the like. From another point of view, during the electroless plating process EP, each of the protective patterns 200 is formed in the corresponding recess and is formed to protrude from the surface S111 of the dielectric layer 111. That is, the thickness of the protective pattern 200 is selected to allow the surface S200 of the protective pattern 200 being located at a level height higher than the surface S111 of the dielectric layer 111. In some embodiments, the thickness of the protective pattern 200 in the package structure 30 is in a range of about 0.5 μm to about 10 μm.

In accordance with an embodiment, a package structure including a substrate component, a redistribution structure, and a probe head is provided. The substrate component is laterally covered by an insulating encapsulation. The redistribution structure is disposed over the substrate component and the insulating encapsulation and is electrically connected with the substrate component at a first side, wherein the redistribution structure comprises: a dielectric layer, at least one conductive pad and at least one conductive pattern. The dielectric layer is at a second side opposite to the first side. The at least one conductive pad is disposed in the dielectric layer, wherein a portion of the at least one conductive pad is exposed by the dielectric layer. The at least one conductive pattern is in contact with the portion of the at least one conductive pad, wherein a hardness of the at least one conductive pattern is greater than a hardness of the at least one conductive pad. The probe head is electrically connected with the at least one conductive pattern and the at least one conductive pad.

In accordance with an embodiment, a package structure including a substrate component, a redistribution structure, and a probe head is provided. The substrate component comprises a core layer, a first build-up structure and a second build-up structure disposed on opposite sides of the core layer and electrically coupled to each other by through core vias penetrating through the core layer. The redistribution structure comprises a first portion, a second portion and a third portion, the third portion disposed over and electrically coupled to the first build-up structure of the substrate component, the first portion stacked on the third portion along a first direction and electrically coupled to the third portion, and the second portion disposed between and electrically coupled to the third portion and the first portion, wherein the first portion comprises: a dielectric layer, at least one conductive pad and at least one conductive pattern. The at least one conductive pad is laterally covered by the dielectric layer along a second direction perpendicular to the first direction, wherein a portion of the at least one conductive pad is exposed by the dielectric layer. The at least one conductive pattern is in contact with the portion of the at least one conductive pad, wherein a hardness of the at least one protective pattern is greater than a hardness of the at least one conductive pad. The probe head is electrically connected with the at least one conductive pattern and the at least one conductive pad.

In accordance with an embodiment, a method of manufacturing a package structure including the following steps is provided. A redistribution structure is formed over a first carrier, wherein the redistribution structure comprises first conductive pads formed in a first dielectric layer, and second conductive pads formed over a second dielectric layer, wherein the first conductive pads and the first dielectric layer are in contact with the first carrier, the second dielectric layer is farthest away from the first carrier. The redistribution structure is bonded to a second carrier and the first carrier is de-bonded to exposed surfaces of the first conductive pads and a surface of the first dielectric layer. An electroless plating process is performed to selectively form protective patterns on the exposed surfaces of the first conductive pads. A substrate component is bonded onto the redistribution structure through conductive joints, wherein the conductive joints are in contact with the second conductive pads. An insulating encapsulation is formed on the redistribution structure to laterally cover the substrate component. A probe head is provided to engage with the protective patterns.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate component laterally covered by an insulating encapsulation;
a redistribution structure disposed over the substrate component and the insulating encapsulation and electrically connected with the substrate component at a first side, wherein the redistribution structure comprises:
a dielectric layer at a second side opposite to the first side;
at least one conductive pad disposed in the dielectric layer, wherein a portion of the at least one conductive pad is exposed by the dielectric layer; and
at least one conductive pattern in contact with the portion of the at least one conductive pad, wherein a hardness of the at least one conductive pattern is greater than a hardness of the at least one conductive pad; and
a probe head electrically connected with the at least one conductive pattern and the at least one conductive pad.

2. The package structure of claim 1, wherein the at least one conductive pattern is protruded from the dielectric layer.

3. The package structure of claim 1, wherein the portion of the at least one conductive pad is a surface facing toward the probe head.

4. The package structure of claim 1, wherein the portion of the at least one conductive pad includes a surface facing toward the probe head and a sidewall contacting with the surface.

5. The package structure of claim 1, wherein the portion of the at least one conductive pad includes a surface facing toward the probe head and a sidewall contacting with the surface.

6. The package structure of claim 1, wherein a surface of the at least one conductive pattern facing toward the probe head is located at a level height higher than that of a surface of the dielectric layer facing toward the probe head.

7. The package structure of claim 1, further comprising:
a circuit board electrically connected with the substrate component, wherein the substrate component is located between the circuit board and the redistribution structure.

8. The package structure of claim 1, wherein the substrate component comprises:
a core layer;
a first build-up structure and a second build-up structure disposed on opposing sides of the core layer, wherein the first build-up structure is located nearer to the redistribution structure than the second build-up structure; and
through core vias penetrating through the core layer and coupled to the first and second build-up structures.

9. The package structure of claim 1, wherein a material of the at least one conductive pattern comprises Ti, Ta, TiN, TaN, Ni, NiV, NiP Cr, Au or Pt.

10. A package structure, comprising:
a substrate component comprising a core layer, a first build-up structure and a second build-up structure disposed on opposite sides of the core layer and electrically coupled to each other by through core vias penetrating through the core layer;
a redistribution structure comprising a first portion, a second portion and a third portion, the third portion disposed over and electrically coupled to the first build-up structure of the substrate component, the first portion stacked on the third portion along a first direction and electrically coupled to the third portion, and the second portion disposed between and electrically coupled to the third portion and the first portion, wherein the first portion comprises:
a dielectric layer;
at least one conductive pad laterally covered by the dielectric layer along a second direction perpendicular to the first direction, wherein a portion of the at least one conductive pad is exposed by the dielectric layer; and
at least one protective pattern in contact with the portion of the at least one conductive pad, wherein a hardness of the at least one protective pattern is greater than a hardness of the at least one conductive pad; and
a probe head electrically connected with the at least one protective pattern and the at least one conductive pad.

11. The package structure of claim 10, wherein the probe head is in directly contact with the at least one protective pattern.

12. The package structure of claim 10, wherein the portion of the at least one conductive pad is a surface facing toward the probe head.

13. The package structure of claim 12, wherein the surface of the at least one conductive pad is coplanar with a surface of the dielectric layer facing toward the probe head.

14. The package structure of claim 12, wherein the surface of the at least one conductive pad is lower than a surface of the dielectric layer facing toward the probe head.

15. The package structure of claim 10, wherein the portion of the at least one conductive pad includes a surface facing toward the probe head and a sidewall contacting with the surface.

16. The package structure of claim 10, wherein the first portion further comprises at least one conductive via embedded in the dielectric layer and in contact with the at least one conductive pad, and the at least one conductive via is tapered from the third portion toward the first portion.

17. A manufacturing method of a package structure, comprising:
forming a redistribution structure over a first carrier, wherein the redistribution structure comprises first conductive pads formed in a first dielectric layer, and second conductive pads formed over a second dielectric layer, wherein the first conductive pads and the first dielectric layer are in contact with the first carrier, the second dielectric layer is farthest away from the first carrier;
bonding the redistribution structure to a second carrier and de-bonding the first carrier to exposed surfaces of the first conductive pads and a surface of the first dielectric layer;
performing an electroless plating process to selectively form protective patterns on the exposed surfaces of the first conductive pads;
bonding a substrate component onto the redistribution structure through conductive joints, wherein the conductive joints are in contact with the second conductive pads;
forming an insulating encapsulation on the redistribution structure to laterally cover the substrate component; and
providing a probe head to engage with the protective patterns.

18. The manufacturing method of claim 17, wherein during de-bonding the first carrier, the exposed surfaces of the first conductive pads are substantially coplanar with the exposed surface of the first dielectric layer.

19. The manufacturing method of claim 17, wherein after de-bonding the first carrier and before performing the electroless plating process, the first dielectric layer is partially removed to expose sidewalls of the first conductive pads.

20. The manufacturing method of claim 17, wherein after de-bonding the first carrier and before performing the electroless plating process, each of the first conductive pads is partially removed to form recesses.
